(19) United States
(12) Patent Application Publication
(10) Pub. No.: US 2026/0322358 A1
(43) Pub. Date: Oct. 15, 2026

(54) COUPLER CIRCUIT WITH ACTIVE INDUCTOR AND ELECTRONIC DEVICE INCLUDING THE SAME

(71) Applicant: Samsung Electronics Co., Ltd., Suwon-si (KR)

(72) Inventors: Ickhyun Song, Seoul (KR); Seunghyeon Park, Seoul (KR); Seonho Shin, Seoul (KR)

(73) Assignee: Industry-University Cooperation Foundation Hanyang University, Seoul (KR)

(21) Appl. No.: 19/555,346

(22) Filed: Mar. 3, 2026

(30) Foreign Application Priority Data
Apr. 10, 2025 (KR) 10-2025-0046651

(51) Int. Cl. H03H 11/30; H03H 11/36

(52) U.S. Cl. CPC H03H 11/30; H03H 11/367

(57) ABSTRACT

A coupler circuit includes a signal line, a coupled line, a first impedance control circuit and a second impedance control circuit. The signal line is disposed between an input port and an output port. The coupled line is disposed between a coupled port and an isolation port. The first impedance control circuit includes a first active inductor configured without a passive element, is electrically connected to the isolation port and adjusts a first impedance of the isolation port. The second impedance control circuit includes a second active inductor configured without a passive element, is electrically connected to the output port and adjusts a second impedance of the output port.

### CROSS-REFERENCE TO RELATED APPLICATION

This application claims priority under 35 USC § 119 to Korean Patent Application No. 10-2025-0046651 filed on Apr. 10, 2025 in the Korean Intellectual Property Office (KIPO), the contents of which are herein incorporated by reference in their entirety.

### TECHNICAL FIELD

This disclosure relates generally to semiconductor integrated circuits, and more particularly to coupler circuits with active inductors and electronic devices including the coupler circuits.

### BACKGROUND

Radio frequency (RF) sources, such as RF amplifiers, may provide RF signals. When an RF signal generated by an RF source is provided to a load, such as to an antenna, a portion of the RF signal may be reflected back from the load. An RF coupler may be included in a signal path between the RF source and the load to provide an indication of forward RF power of the RF signal traveling from the RF amplifier to the load and/or an indication of reverse RF power reflected back from the load. RF couplers include, for example, direction couplers, bi-directional couplers, multi-band couplers (e.g., dual-band couplers), etc.

RF couplers typically cause an insertion loss in an RF signal path. Thus, an RF signal received at the power input port of an RF coupler may have a lower power when provided at the power output port of the RF coupler. For example, insertion loss may result from a portion of the RF signal being provided to a coupled port (or to an isolation port) and/or from losses associated with a main transmission line of the RF coupler.

### SUMMARY

At least one example embodiment of the present disclosure provides a coupler circuit capable of preventing isolation degradation and reducing loss.

At least one example embodiment of the present disclosure provides an electronic device including the coupler circuit.

According to example embodiments, a coupler circuit includes a signal line, a coupled line, a first impedance control circuit and a second impedance control circuit. The signal line is disposed between an input port and an output port. The coupled line is disposed between a coupled port and an isolation port. The first impedance control circuit includes a first active inductor configured without a passive element, is electrically connected to the isolation port and adjusts a first impedance of the isolation port. The second impedance control circuit includes a second active inductor configured without a passive element, is electrically connected to the output port and adjusts a second impedance of the output port.

According to example embodiments, an electronic device includes a first circuit, a second circuit and a coupler circuit. The first circuit generates a first signal. The second circuit receives the first signal. The coupler circuit is disposed between the first circuit and the second circuit, and transmits the first signal from the first circuit to the second circuit. The coupler circuit includes a signal line, a coupled line, a first impedance control circuit and a second impedance control circuit. The signal line is disposed between an input port and an output port. The input port receives the first signal. The output port outputs the first signal. The coupled line is disposed between a coupled port and an isolation port. The first impedance control circuit includes a first active inductor configured without a passive element, is electrically connected to the isolation port and adjusts a first impedance of the isolation port. The second impedance control circuit includes a second active inductor configured without a passive element, is electrically connected to the output port and adjusts a second impedance of the output port.

According to example embodiments, a coupler circuit includes a signal line, a coupled line, and a first impedance control circuit. The signal line is disposed between an input port and an output port. The coupled line is disposed between a coupled port and an isolation port. The first impedance control circuit is electrically connected to the isolation port, and adjusts a first impedance of the isolation port. The first impedance control circuit includes a first active inductor. The first active inductor adjusts the first impedance, and includes a first current source, a first transistor, a second transistor, and a second current source. The first current source is electrically connected between a power supply voltage and a first node. The first transistor is electrically connected between the power supply voltage and a second node, and includes a gate electrode electrically connected to the first node. The second transistor is electrically connected between the first node and a ground voltage, and includes a gate electrode electrically connected to the second node. The second current source is electrically connected between the second node and the ground voltage. The first active inductor further includes a third transistor, a first capacitor, a fourth transistor, a first resistor and a fifth transistor. The third transistor is electrically connected between the second node and the isolation port, and controls an electrical connection between the first active inductor and the isolation port. The first capacitor adjusts the first impedance. The fourth transistor is electrically connected between the first capacitor and the isolation port, and controls an electrical connection between the first capacitor and the isolation port. The first resistor adjusts the first impedance. The fifth transistor is electrically connected between the first resistor and the isolation port, and controls an electrical connection between the first resistor and the isolation port.

The coupler circuit and the electronic device according to example embodiments may include the first impedance control circuit, which includes the first active inductor electrically connected to the isolation port and is implemented without the passive component, and may include the second impedance control circuit, which includes the second active inductor electrically connected to the output port and is implemented without the passive component. Accordingly, the circuit size may be reduced and the area utilization may be improved, as compared with a coupler circuit using a passive inductor in related art. In addition, the impedances of the ports may be adjusted, controlled, and changed in real time and/or dynamically using the active inductors. Accordingly, isolation degradation may be prevented and loss may be reduced or minimized, so that the coupler circuit may have improved or enhanced performance.

### BRIEF DESCRIPTION OF THE DRAWINGS

Illustrative, non-limiting example embodiments will be more clearly understood from the following detailed description taken in conjunction with the accompanying drawings.

FIG. 1 is a block diagram illustrating a coupler circuit according to example embodiments.

FIGS. 2, 3, 4, 5, 6, and 7 are circuit diagrams illustrating example embodiments of a first impedance control circuit included in a coupler circuit of FIG. 1.

FIG. 8 is a block diagram illustrating a coupler circuit according to example embodiments.

FIGS. 9, 10A, 10B, 10C, and 10D are diagrams for describing a coupler circuit according to example embodiments.

FIGS. 11 and 12 are block diagrams illustrating a coupler circuit according to example embodiments.

FIG. 13 is a block diagram illustrating an electronic device according to example embodiments.

FIGS. 14 and 15 are block diagrams illustrating example embodiments of an electronic device of FIG. 13.

### DETAILED DESCRIPTION OF THE EMBODIMENTS

Various example embodiments will be described more fully with reference to the accompanying drawings, in which embodiments are shown. The present disclosure may, however, be embodied in many different forms and should not be construed as limited to the embodiments set forth herein. Like reference numerals refer to like elements throughout this application.

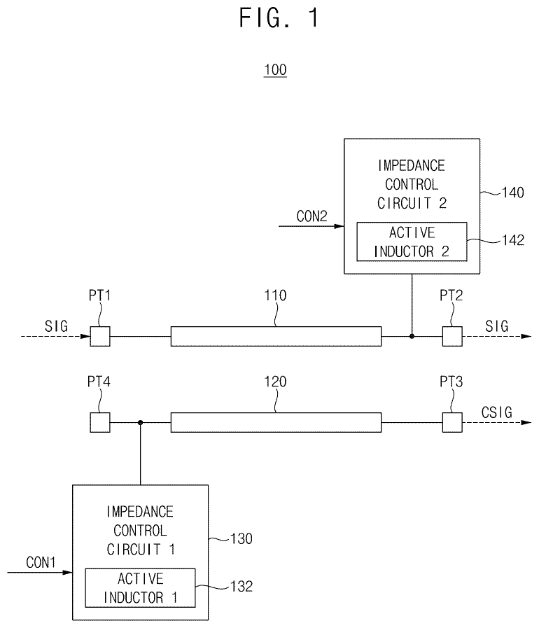

FIG. 1 is a block diagram illustrating a coupler circuit according to example embodiments.

Referring to FIG. 1, a coupler circuit 100 includes an input port PT1, an output port PT2, a coupled port PT3, an isolation port PT4, a signal line 110, a coupled line 120, a first impedance control circuit 130, and a second impedance control circuit 140.

In some example embodiments, the coupler circuit 100 may be used to stably transmit a signal from one circuit to another circuit. For example, the power of a transmission line may be coupled to a port such that a signal output from a transmission circuit can be used in a reception circuit, while the performance degradation due to a reflected signal occurring in the reception circuit may be prevented. Example embodiments of an electronic device including the coupler circuit 100 will be described with reference to FIGS. 13, 14, and 15.

The input port PT1 may receive a signal SIG to be transmitted, and the output port PT2 may output the signal SIG to be transmitted. The coupled port PT3 may output a coupled signal CSIG that is generated and/or extracted based on the signal SIG to be transmitted. The isolation port PT4 may prevent a signal received at the output port PT2 from being transferred to the input port PT1. The input port PT1, the output port PT2, the coupled port PT3, and the isolation port PT4 may be referred to as a first port, a second port, a third port, and a fourth port, respectively.

The signal line 110 is disposed or arranged between the input port PT1 and the output port PT2. The signal line 110 may perform a role or function of transmitting the signal SIG received at the input port PT1 to the output port PT2. The signal line 110 may be referred to as a first transmission line, a main line, etc.

The coupled line 120 is disposed or arranged between the coupled port PT3 and the isolation port PT4. The coupled line 120 may be disposed adjacent to the signal line 110 for coupling with the signal line 110, and may extract the coupled signal CSIG from the signal line 110. The coupled line 120 may be referred to as a second transmission line.

In some example embodiments, the signal line 110 and the coupled line 120 may be implemented using microstrips, strip lines, coplanar lines, and the like. The electromagnetic coupling mechanism, which may include inductive or capacitive coupling, may be typically provided by two parallel or overlapped transmission lines.

The first impedance control circuit 130 is electrically connected to the isolation port PT4, and adjusts a first impedance of the isolation port PT4. The first impedance control circuit 130 includes a first active inductor 132 that is configured or implemented without a passive element. For example, the first impedance control circuit 130 may adjust or control the first impedance based on a first impedance control signal CON1 and using the first active inductor 132.

The second impedance control circuit 140 is electrically connected to the output port PT2, and adjusts a second impedance of the output port PT2. The second impedance control circuit 140 includes a second active inductor 142 that is configured or implemented without any passive component. For example, the second impedance control circuit 140 may adjust or control the second impedance based on the second impedance control signal CON2 and using the second active inductor 142.

Unlike passive inductors implemented using coils in related art, the active inductors 132 and 142 included in the impedance control circuits 130 and 140 according to example embodiments may be implemented without coils, and thus the impedance control circuits 130 and 140 may be implemented with a relatively small size and area.

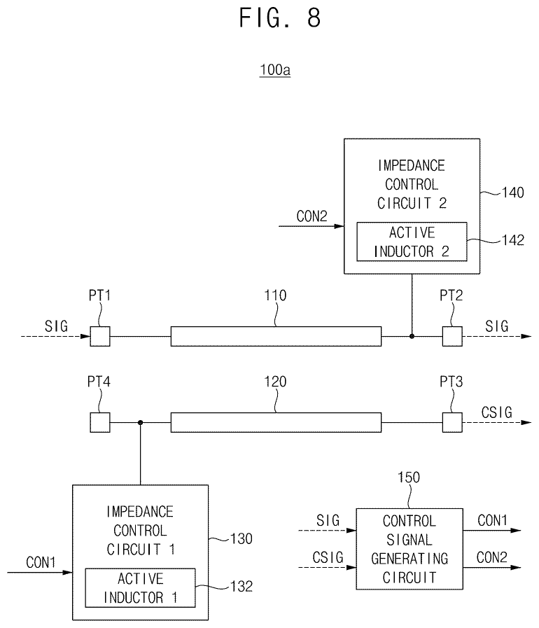

In some example embodiments, the first impedance control signal CON1 for controlling the first impedance and the second impedance control signal CON2 for controlling the second impedance may be provided from the outside of the coupler circuit 100. However, example embodiments are not limited thereto, and the coupler circuit 100 may further include a configuration for generating the first impedance control signal CON1 and the second impedance control signal CON2, as will be described with reference to FIG. 8.

In coupler circuits, including RF couplers, the termination impedance on the isolation port plays an important role in controlling the directivity of the coupler. In coupler circuits in related art, termination impedance may be implemented at a fixed impedance value, which provides a desired directivity for only a particular range of frequencies. Therefore, if the coupler circuit is intended to be used over multiple frequency bands, for example, it is preferable to use an adjustable termination impedance. In related art, the terminal impedance was implemented using passive elements, and there was a problem of increasing the size and area.

The coupler circuit 100 according to example embodiments may include the first impedance control circuit 130, which includes the first active inductor 132 electrically connected to the isolation port PT4 and is implemented without the passive component, and may include the second impedance control circuit 140, which includes the second active inductor 142 electrically connected to the output port PT2 and is implemented without the passive component. Accordingly, the circuit size may be reduced and the area utilization may be improved, as compared with a coupler circuit using a passive inductor in related art. In addition, the impedances of the ports PT4 and PT2 may be adjusted, controlled, and changed in real time and/or dynamically using the active inductors 132 and 142. Accordingly, isolation degradation may be prevented and loss may be reduced or minimized, so that the coupler circuit 100 may have improved or enhanced performance.

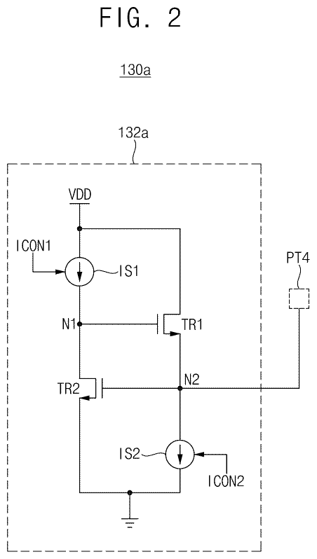

FIGS. 2, 3, 4, 5, 6, and 7 are circuit diagrams illustrating example embodiments of a first impedance control circuit included in a coupler circuit of FIG. 1.

Referring to FIG. 2, a first impedance control circuit 130a may include a first active inductor 132a. The first active inductor 132a may include a first current source IS1, a first transistor TR1, a second transistor TR2 and a second current source IS2.

The first current source IS1 may be electrically connected between a power supply voltage VDD and a first node N1. The first transistor TR1 may be electrically connected between the power supply voltage VDD and a second node N2, and may include a gate electrode electrically connected to the first node N1. The second transistor TR2 may be electrically connected between the first node N1 and a ground voltage, and may include a gate electrode electrically connected to the second node N2. The second current source IS2 may be electrically connected between the second node N2 and the ground voltage. Three parallel straight lines with different lengths electrically connected to the second transistor TR2 and the second current source IS2 may represent the ground voltage.

The first impedance control circuit 130a may be electrically connected to the isolation port PT4 through the second node N2.

In some example embodiments, each of the first transistor TR1 and the second transistor TR2 may be an n-type metal oxide semiconductor (NMOS) transistor. However, example embodiments are not limited thereto.

In some example embodiments, the first current source IS1 may generate a first current, the second current source IS2 may generate a second current, and at least one of the first current and the second current may be adjustable or changeable. For example, the first current may be adjusted based on the first current control signal ICON1, and the second current may be adjusted based on the second current control signal ICON2. Although FIG. 2 illustrates that both the first and second currents are adjustable, example embodiments are not limited thereto. For example, when only the first current is adjustable, the second current control signal ICON2 may be omitted. For example, when only the second current is adjustable, the first current control signal ICON1 may be omitted.

In some example embodiments, each of the first current source IS1 and the second current source IS2 may include a plurality of transistors. For example, the first current source IS1 may include a plurality of transistors electrically connected in parallel between the power supply voltage VDD and the first node N1, and the amount of the first current may be adjusted depending on the number of transistors turned on among the plurality of transistors. However, example embodiments are not limited thereto.

In some example embodiments, when at least one of the first current and the second current is adjusted based on at least one of the first current control signal ICON1 and the second current control signal ICON2, an impedance of the first active inductor 132a may be changed. In addition, when the impedance of the first active inductor 132a is changed, the first impedance of the isolation port PT4 may be changed. In other words, the first current control signal ICON1 and the second current control signal ICON2 may be included in the first impedance control signal CON1 for controlling the first impedance.

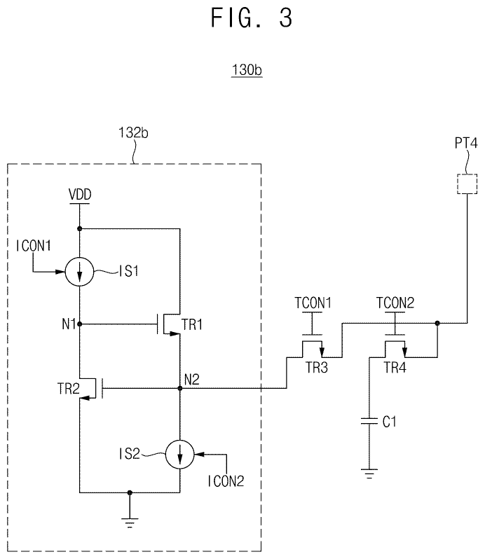

Referring to FIG. 3, a first impedance control circuit 130b may include a first active inductor 132b, a third transistor TR3, a fourth transistor TR4, and a first capacitor C1.

As compared with the first impedance control circuit 130a of FIG. 2, the first impedance control circuit 130b may further include the third transistor TR3, the fourth transistor TR4, and the first capacitor C1. The first active inductor 132b may be substantially the same as the first active inductor 132a in FIG. 2. The descriptions repeated with or overlapping with descriptions of FIG. 2 will be omitted in the interest of brevity.

The third transistor TR3 may be electrically connected between the second node N2 and the isolation port PT4, and may include a gate electrode receiving a first transistor control signal TCON1. The fourth transistor TR4 and the first capacitor C1 may be electrically connected in series between the isolation port PT4 and the ground voltage. The fourth transistor TR4 may include a gate electrode receiving a second transistor control signal TCON2.

In some example embodiments, each of the third transistor TR3 and the fourth transistor TR4 may be an NMOS transistor. However, example embodiments are not limited thereto.

In some example embodiments, an electrical connection between the first active inductor 132b and the isolation port PT4 may be controlled using the third transistor TR3, and an electrical connection between the first capacitor C1 and the isolation port PT4 may be controlled using the fourth transistor TR4.

For example, the first active inductor 132b may be electrically connected to the isolation port PT4 when the third transistor TR3 is turned on based on the first transistor control signal TCON1, and the first active inductor 132b may be electrically disconnected from the isolation port PT4 when the third transistor TR3 is turned off based on the first transistor control signal TCON1. Similarly, the first capacitor C1 may be electrically connected to the isolation port PT4 when the fourth transistor TR4 is turned on based on the second transistor control signal TCON2, and the first capacitor C1 may be electrically disconnected from the isolation port PT4 when the fourth transistor TR4 is turned off based on the second transistor control signal TCON2.

In some example embodiments, when the first active inductor 132b and the first capacitor C1 are electrically connected to and electrically disconnected from the isolation port PT4 by turning on and off the third transistor TR3 and the fourth transistor TR4 based on the first transistor control signal TCON1 and the second transistor control signal TCON2, the first impedance of the isolation port PT4 may be changed. In other words, the first transistor control signal TCON1 and the second transistor control signal TCON2 may be included in the first impedance control signal CON1 for controlling the first impedance.

In some example embodiments, an imaginary part of the first impedance may be decreased using the third transistor TR3 and the first active inductor 132b, and the imaginary part of the first impedance may be increased using the fourth transistor TR4 and the first capacitor C1. For example, when the third transistor TR3 is turned on and the first active inductor 132b is electrically connected to the isolation port PT4, the imaginary part of the first impedance may be decreased. For example, when the fourth transistor TR4 is turned on and the first capacitor C1 is electrically connected to the isolation port PT4, the imaginary part of the first impedance may be increased. However, example embodiments are not limited thereto.

Although FIG. 3 illustrates the components disposed between the first active inductor 132b, the first capacitor C1, and the isolation port PT4 as the transistors TR3 and TR4, example embodiments are not limited thereto, and arbitrary switch structures may be used other than the transistors TR3 and TR4. The first impedance control circuit 130b may have a single pole double throw (SPDT) structure in which the first active inductor 132b and the first capacitor C1 are selectively electrically connected to the isolation port PT4 using two transistors TR3 and TR4 or switch structures.

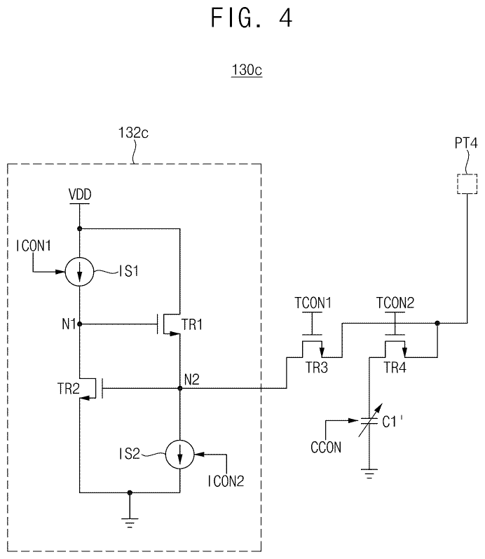

Referring to FIG. 4, a first impedance control circuit 130c may include a first active inductor 132c, a third transistor TR3, a fourth transistor TR4, and a first capacitor C1′.

As compared with the first impedance control circuit 130b of FIG. 3, a configuration of the first capacitor C1′ may be changed in the first impedance control circuit 130c. The first active inductor 132c may be substantially the same as the first active inductor 132a in FIG. 2, and the third transistor TR3 and the fourth transistor TR4 may be substantially the same as those described with reference to FIG. 3. The descriptions repeated with or overlapping with descriptions of FIGS. 2 and 3 will be omitted in the interest of brevity.

In some example embodiments, a capacitance of the first capacitor C1′ may be adjustable. For example, the capacitance of the first capacitor C1′ may be adjusted based on a first capacitor control signal CCON. In other words, the first capacitor C1′ may be a variable capacitor.

In some example embodiments, the first capacitor C1′ may be implemented in the form of a capacitor array including a plurality of capacitors. For example, the capacitance of the first capacitor C1′ may be adjusted depending on the number of capacitors electrically connected to the isolation port PT4 among the plurality of capacitors. However, example embodiments are not limited thereto.

In some example embodiments, when the capacitance of the first capacitor C1′ is adjusted based on the first capacitor control signal CCON, the first impedance of the isolation port PT4 may be changed. In other words, the first capacitor control signal CCON may be included in the first impedance control signal CON1 for controlling the first impedance.

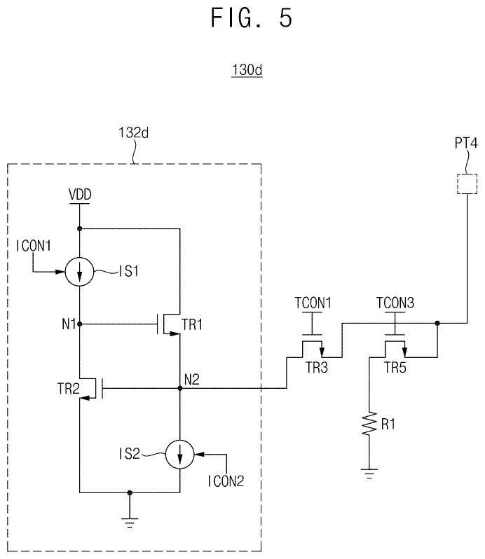

Referring to FIG. 5, a first impedance control circuit 130d may include a first active inductor 132d, a third transistor TR3, a fifth transistor TR5, and a first resistor R1.

As compared with the first impedance control circuit 130a of FIG. 2, the first impedance control circuit 130d may further include the third transistor TR3, the fifth transistor TR5, and the first resistor R1. The first active inductor 132d may be substantially the same as the first active inductor 132a in FIG. 2, and the third transistor TR3 may be substantially the same as that described with reference to FIG. 3. The descriptions repeated with or overlapping with descriptions of FIGS. 2 and 3 will be omitted in the interest of brevity.

The fifth transistor TR5 and the first resistor R1 may be electrically connected in series between the isolation port PT4 and the ground voltage. The fifth transistor TR5 may include a gate electrode receiving a third transistor control signal TCON3.

In some example embodiments, the fifth transistor TR5 may be an NMOS transistor. However, example embodiments are not limited thereto.

In some example embodiments, an electrical connection between the first resistor R1 and the isolation port PT4 may be controlled using the fifth transistor TR5. For example, the first resistor R1 may be electrically connected to the isolation port PT4 when the fifth transistor TR5 is turned on based on the third transistor control signal TCON3, and the first resistor R1 may be electrically disconnected from the isolation port PT4 when the fifth transistor TR5 is turned off based on the third transistor control signal TCON3.

In some example embodiments, when the first resistor R1 is electrically connected to and disconnected from the isolation port PT4 by turning on and off the fifth transistor TR5 based on the third transistor control signal TCON3, the first impedance of the isolation port PT4 may be changed. In other words, the third transistor control signal TCON3 may be included in the first impedance control signal CON1 for controlling the first impedance.

In some example embodiments, the imaginary part of the first impedance may be decreased using the third transistor TR3 and the first active inductor 132d, and the imaginary part of the first impedance may be increased using the fifth transistor TR5 and the first resistor R1. For example, when the fifth transistor TR5 is turned on and the first resistor R1 is electrically connected to the isolation port PT4, the imaginary part of the first impedance may be increased. However, example embodiments are not limited thereto.

In some example embodiments, arbitrary switch structures may be used other than the transistors TR3 and TR5. The first impedance control circuit 130d may have an SPDT structure in which the first active inductor 132d and the first resistor R1 are selectively electrically connected to the isolation port PT4 using two transistors TR3 and TR5 or switch structures.

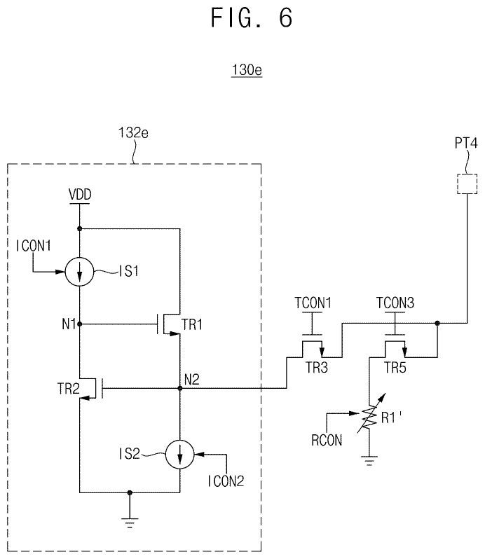

Referring to FIG. 6, a first impedance control circuit 130e may include a first active inductor 132e, a third transistor TR3, a fifth transistor TR5, and a first resistor R1′.

As compared with the first impedance control circuit 130d of FIG. 5, a configuration of the first resistor R1′ may be changed in the first impedance control circuit 130e. The first active inductor 132e may be substantially the same as the first active inductor 132a in FIG. 2, and the third transistor TR3 and the fifth transistor TR5 may be substantially the same as those described with reference to FIGS. 3 and 5, respectively. The descriptions repeated with or overlapping with descriptions of FIGS. 2, 3, and 5 will be omitted in the interest of brevity.

In some example embodiments, a resistance of the first resistor R1′ may be adjustable. For example, the resistance of the first resistor R1′ may be adjusted based on the first resistor control signal RCON. In other words, the first resistor R1′ may be a variable resistor.

In some example embodiments, the first resistor R1′ may be implemented in the form of a resistor array including a plurality of resistors. For example, the resistance of the first resistor R1′ may be adjusted depending on the number of resistors among the plurality of resistors electrically connected to the isolation port PT4. However, example embodiments are not limited thereto.

In some example embodiments, when the resistance of the first resistor R1′ is adjusted based on the first resistance control signal RCON, the first impedance of the isolation port PT4 may be changed. In other words, the first resistance control signal RCON may be included in the first impedance control signal CON1 for controlling the first impedance.

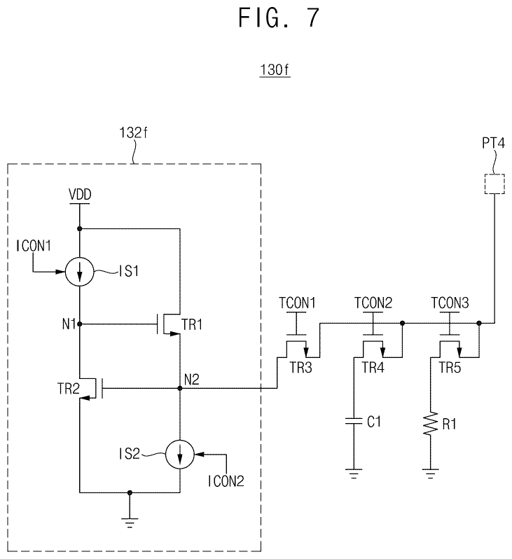

Referring to FIG. 7, a first impedance control circuit 130f may include a first active inductor 132f, a third transistor TR3, a fourth transistor TR4, a fifth transistor TR5, a first capacitor C1, and a first resistor R1.

As compared with the first impedance control circuit 130a of FIG. 2, the first impedance control circuit 130f may further include the third transistor TR3, the fourth transistor TR4, the fifth transistor TR5, the first capacitor C1, and the first resistor R1. The first active inductor 132f may be substantially the same as the first active inductor 132a in FIG. 2, and the third transistor TR3, the fourth transistor TR4, the fifth transistor TR5, the first capacitor C1, and the first resistor R1 may be substantially the same as those described with reference to FIGS. 3 and 5, respectively. The descriptions repeated with or overlapping with descriptions of FIGS. 2, 3, and 5 will be omitted in the interest of brevity.

In some example embodiments, the imaginary part of the first impedance may be decreased using the third transistor TR3 and the first active inductor 132f, and the imaginary part of the first impedance may be increased using the fourth transistor TR4 and the first capacitor C1, and using the fifth transistor TR5 and the first resistor R1.

In some example embodiments, the first capacitor C1 may be implemented as a variable capacitor similar to the example embodiment of FIG. 4, and/or the first resistor R1 may be implemented as a variable resistor similar to the example embodiment of FIG. 6.

In some example embodiments, arbitrary switch structures may be used other than the transistors TR3, TR4, and TR5. The first impedance control circuit 130f may have a single pole triple throw (SP3T) structure in which the first active inductor 132d, the first capacitor C1, and the first resistor R1 are selectively electrically connected to the isolation port PT4 using three transistors TR3, TR4, and TR5 or switch structures.

Although not illustrated in detail, the second impedance control circuit 140 may also be implemented by any one of the example embodiments illustrated in FIGS. 2, 3, 4, 5, 6, and 7. In some example embodiments, the second impedance control circuit 140 may have a configuration substantially the same as that of the first impedance control circuit 130, or may have a configuration different from that of the first impedance control circuit 130.

FIG. 8 is a block diagram illustrating a coupler circuit according to example embodiments.

Referring to FIG. 8, a coupler circuit 100a includes an input port PT1, an output port PT2, a coupled port PT3, an isolation port PT4, a signal line 110, a coupled line 120, a first impedance control circuit 130, a second impedance control circuit 140, and a control signal generating circuit 150.

As compared with the coupler circuit 100 of FIG. 1, the coupler circuit 100a may further include the control signal generating circuit 150. The input port PT1, the output port PT2, the coupled port PT3, the isolation port PT4, the signal line 110, the coupled line 120, the first impedance control circuit 130 and the second impedance control circuit 140 may be substantially the same as those described with reference to FIG. 1. The descriptions repeated with or overlapping with descriptions of FIG. 1 will be omitted in the interest of brevity.

The control signal generating circuit 150 may generate the first impedance control signal CON1, may provide the first impedance control signal CON1 to the first impedance control circuit 130, may generate the second impedance control signal CON2, and may provide the second impedance control signal CON2 to the second impedance control circuit 140.

In some example embodiments, the control signal generating circuit 150 may generate the first impedance control signal CON1 and the second impedance control signal CON2 based on at least one of the signal SIG to be transmitted and the coupled signal CSIG. For example, the first impedance of the isolation port PT4 and/or the second impedance of the output port PT2 may be adjusted based on a frequency, amplitude, etc., of at least one of the signal SIG and the coupled signal CSIG.

For example, the control signal generating circuit 150 may be electrically connected to the input port PT1 to receive the signal SIG, and may generate the first impedance control signal CON1 and the second impedance control signal CON2 based on the signal SIG. For another example, the control signal generating circuit 150 may be electrically connected to the coupled port PT3 to receive the coupled signal CSIG, and may generate the first impedance control signal CON1 and the second impedance control signal CON2 based on the coupled signal CSIG. Alternatively, the control signal generating circuit 150 may receive both the signal SIG and the coupled signal CSIG, and may generate the first impedance control signal CON1 and the second impedance control signal CON2 based on the signal SIG and the coupled signal CSIG. Although FIG. 8 illustrates that the control signal generating circuit 150 receives both the signal SIG and the coupled signal CSIG, example embodiments are not limited thereto.

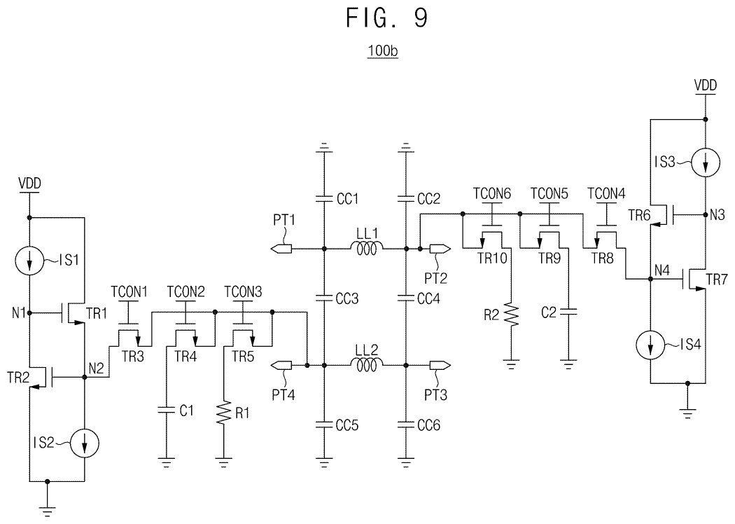

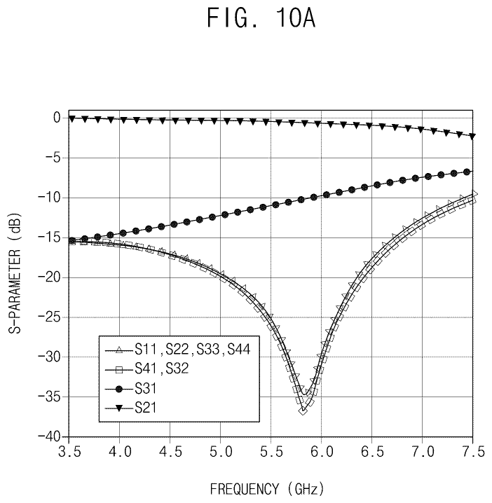

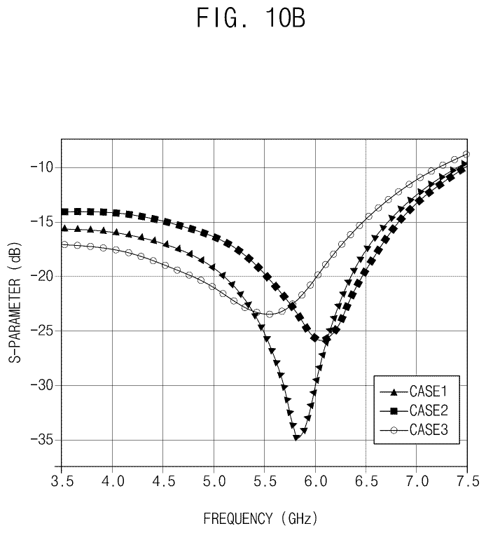

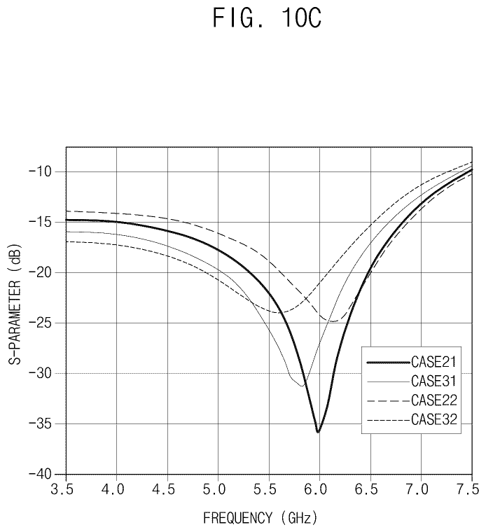

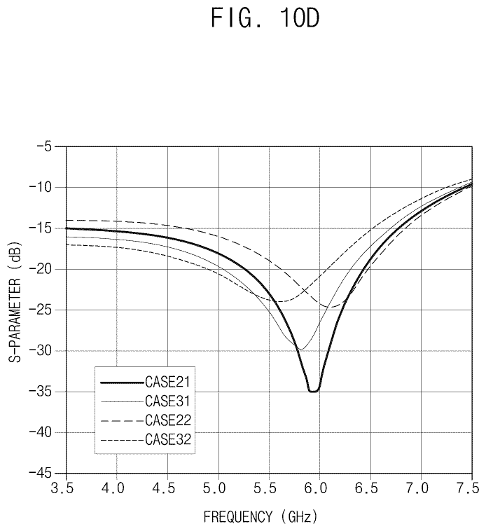

FIGS. 9, 10A, 10B, 10C, and 10D are diagrams for describing a coupler circuit according to example embodiments.

Referring to FIG. 9, a modeled coupler circuit 100b that is generated by modeling the coupler circuit 100 of FIG. 1 is illustrated.

The signal line 110 between the input port PT1 and the output port PT2, and the coupled line 120 between the coupled port PT3 and the isolation port PT4, may be modeled with two inductors LL1 and LL2 and six capacitors CC1, CC2, CC3, CC4, CC5, and CC6.

For example, the inductor LL1 may be electrically connected between the input port PT1 and the output port PT2, and the inductor LL2 may be electrically connected between the coupled port PT3 and the isolation port PT4. The capacitor CC1 may be electrically connected between the input port PT1 and the ground voltage, the capacitor CC2 may be electrically connected between the output port PT2 and the ground voltage, the capacitor CC3 may be electrically connected between the input port PT1 and the isolation port PT4, the capacitor CC4 may be electrically connected between the output port PT2 and the coupled port PT3, the capacitor CC5 may be electrically connected between the isolation port PT4 and the ground voltage, and the capacitor CC6 may be electrically connected between the coupled port PT3 and the ground voltage.

The first impedance control circuit 130 may have a configuration as illustrated in FIG. 7, and the second impedance control circuit 140 may have a configuration substantially the same as that of the first impedance control circuit 130.

For example, the first current source IS1, the second current source IS2, the first transistor TR1, the second transistor TR2, the third transistor TR3, the fourth transistor TR4, the fifth transistor TR5, the first capacitor C1 and the first resistor R1 that are included in the first impedance control circuit 130 may be substantially the same as those described with reference to FIGS. 2 through 7.

For example, the second impedance control circuit 140 may include a third current source IS3, a fourth current source IS4, a sixth transistor TR6, a seventh transistor TR7, an eighth transistor TR8, a ninth transistor TR9, a tenth transistor TR10, a second capacitor C2, and a second resistor R2. The third current source IS3 may be electrically connected between the power supply voltage VDD and a third node N3. The sixth transistor TR6 may be electrically connected between the power supply voltage VDD and the third node N3, and may include a gate electrode electrically connected to a fourth node N4. The seventh transistor TR7 may be electrically connected between the third node N3 and the ground voltage, and may include a gate electrode electrically connected to the fourth node N4. The fourth current source IS4 may be electrically connected between the fourth node N4 and the ground voltage. The third current source IS3, the fourth current source IS4, the sixth transistor TR6, and the seventh transistor TR7 may be included in the second active inductor 142. The eighth transistor TR8 may be electrically connected between the fourth node N4 and the output port PT2, and may include a gate electrode receiving a fourth transistor control signal TCON4. The ninth transistor TR9 and the second capacitor C2 may be electrically connected in series between the output port PT2 and the ground voltage. The ninth transistor TR9 may include a gate electrode receiving a fifth transistor control signal TCON5. The tenth transistor TR10 and the second resistor R2 may be electrically connected in series between the output port PT2 and the ground voltage. The tenth transistor TR10 may include a gate electrode receiving a fifth transistor control signal TCON5.

Referring to FIG. 10A, S-parameters representing the characteristics of a coupler circuit in related art that does not include the first impedance control circuit 130 and the second impedance control circuit 140 are illustrated. Among the S-parameters illustrated in FIG. 10A, S11, S22, S33 and S44 represent reflection coefficients (or reflectivity) of the input port PT1, the output port PT2, the coupled port PT3 and the isolation port PT4, respectively, S41 and S32 represent isolation coefficients (or isolation) of the isolation port PT4 and the coupled port PT3, respectively, S31 represents a coupling coefficient associated with or related to signal leakage from the input port PT1 to the coupled port PT3, and S21 represents a transfer coefficient associated with or related to signal transmission from the input port PT1 to the output port PT2.

Referring to FIG. 10B, the isolation coefficients, e.g., S-parameters S41 and S32, in example embodiments where the first impedance of the isolation port PT4 is adjusted using the first impedance control circuit 130 and/or the second impedance of the output port PT2 is adjusted using the second impedance control circuit 140 in the coupler circuit 100 according to example embodiments are illustrated. In FIG. 10B, CASE1 represents an implementation where the first impedance and/or the second impedance is set to about 50 ohms, CASE2 represents an implementation where the first impedance and/or the second impedance is set to about 70 ohms, and CASE3 represents an implementation where the first impedance and/or the second impedance is set to about 30 ohms. It can be observed that the first impedance and/or the second impedance may be changed using the first impedance control circuit 130 and/or the second impedance control circuit 140.

Referring to FIG. 10C, changes in the isolation coefficients, e.g., S41 among the S-parameters, when changing an impedance of an output port in a comparative coupler circuit in related art, and when adjusting the second impedance of the output port PT2 using the second impedance control circuit 140 in the coupler circuit 100 according to example embodiments are illustrated. In FIG. 10C, CASE21 represents an implementation where the second impedance is set to about 70 ohms in the coupler circuit 100 according to example embodiments, and CASE22 represents an implementation where the impedance of the output port is set to about 70 ohms in the comparative coupler circuit. Similarly, CASE31 represents an implementation where the second impedance is set to about 30 ohms in the coupler circuit 100 according to example embodiments, and CASE32 represents an implementation where the impedance of the output port is set to about 30 ohms in the comparative coupler circuit. As illustrated in CASE21 and CASE31, it can be observed that the isolation degradation is prevented in the coupler circuit 100 according to example embodiments.

Referring to FIG. 10D, changes in the isolation coefficients, e.g., S32 among the S-parameters, when changing an impedance of an isolation port in a comparative coupler circuit in related art, and when adjusting the first impedance of the isolation port PT4 using the first impedance control circuit 130 in the coupler circuit 100 according to example embodiments are illustrated. In FIG. 10D, CASE21 represents an implementation where the first impedance is set to about 70 ohms in the coupler circuit 100 according to example embodiments, and CASE22 represents an implementation where the impedance of the isolation port in the comparative coupler circuit is set to about 70 ohms. Similarly, CASE31 represents an implementation where the first impedance is set to about 30 ohms in the coupler circuit 100 according to example embodiments, and CASE32 represents an implementation where the impedance of the isolation port in the comparative coupler circuit is set to about 30 ohms. As illustrated in CASE21 and CASE31, it can be observed that the isolation degradation is prevented in the coupler circuit 100 according to example embodiments.

Although not illustrated in detail, when the first impedance control circuit 130 is implemented with one of the examples illustrated in FIGS. 2 through 6 and the second impedance control circuit 140 has a configuration substantially the same as that of the first impedance control circuit 130, the second impedance control circuit 140 may be implemented such that at least one of the components illustrated in FIG. 9 is omitted. For example, when the first impedance control circuit 130 is implemented with the example illustrated in FIG. 2, the second impedance control circuit 140 may include only the third current source IS3, the fourth current source IS4, the sixth transistor TR6, and the seventh transistor TR7. For example, when the first impedance control circuit 130 is implemented with the example illustrated in FIG. 3, the second impedance control circuit 140 may include only the third current source IS3, the fourth current source IS4, the sixth transistor TR6, the seventh transistor TR7, the eighth transistor TR8, the ninth transistor TR9, and the second capacitor C2. For example, when the first impedance control circuit 130 is implemented with the example illustrated in FIG. 5, the second impedance control circuit 140 may include only the third current source IS3, the fourth current source IS4, the sixth transistor TR6, the seventh transistor TR7, the eighth transistor TR8, the tenth transistor TR10, and the second resistor R2.

Although the examples where the first impedance control circuit 130 and the second impedance control circuit 140 have the same configuration are described, example embodiments are not limited thereto, and the first impedance control circuit 130 and the second impedance control circuit 140 may have different configurations. For example, when the first impedance control circuit 130 is implemented with the example illustrated in FIG. 7, the second impedance control circuit 140 may be implemented with one of the examples illustrated in FIGS. 2 through 6.

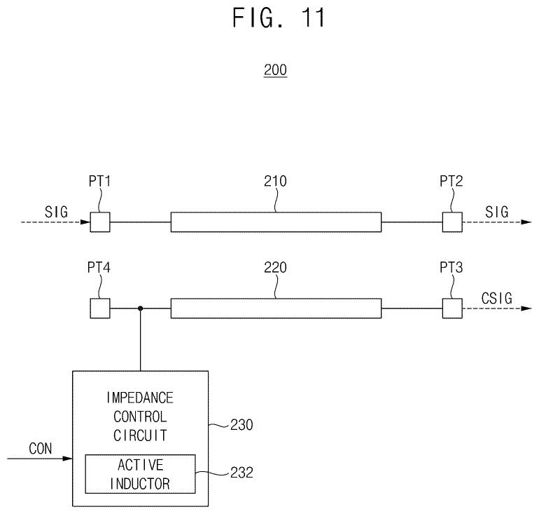

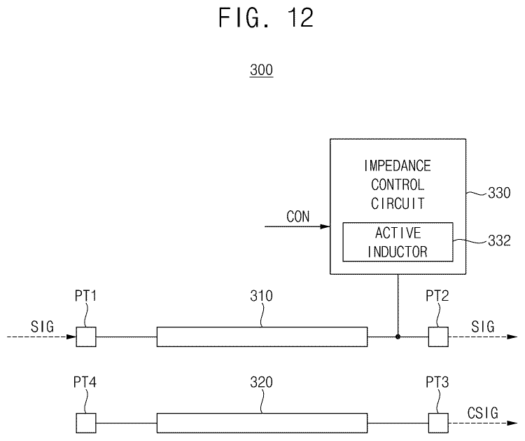

FIGS. 11 and 12 are block diagrams illustrating a coupler circuit according to example embodiments. The descriptions repeated with or overlapping with descriptions of FIG. 1 will be omitted in the interest of brevity.

Referring to FIG. 11, a coupler circuit 200 includes an input port PT1, an output port PT2, a coupled port PT3, an isolation port PT4, a signal line 210, a coupled line 220, and an impedance control circuit 230. The impedance control circuit 230 may be electrically connected to the isolation port PT4, may include an active inductor 232, and may adjust an impedance of the isolation port PT4 based on an impedance control signal CON.

As compared with the coupler circuit 100 of FIG. 1, the coupler circuit 200 may have a configuration in which the second impedance control circuit 140 is omitted. In other words, the coupler circuit 200 may include only one impedance control circuit 230 that is electrically connected to the isolation port PT4 and includes the active inductor 232. The input port PT1, the output port PT2, the coupled port PT3, the isolation port PT4, the signal line 210, the coupled line 220 and the impedance control circuit 230 may be substantially the same as the input port PT1, the output port PT2, the coupled port PT3, the isolation port PT4, the signal line 110, the coupled line 120 and the first impedance control circuit 130 in FIG. 1, respectively.

Referring to FIG. 12, a coupler circuit 300 includes an input port PT1, an output port PT2, a coupled port PT3, an isolation port PT4, a signal line 310, a coupled line 320, and an impedance control circuit 330. The impedance control circuit 330 may be electrically connected to the output port PT2, may include an active inductor 332, and may adjust an impedance of the output port PT2 based on an impedance control signal CON.

As compared with the coupler circuit 100 of FIG. 1, the coupler circuit 300 may have a configuration in which the first impedance control circuit 130 is omitted. In other words, the coupler circuit 300 may include only one impedance control circuit 330 that is electrically connected to the output port PT2 and includes the active inductor 332. The input port PT1, the output port PT2, the coupled port PT3, the isolation port PT4, the signal line 310, the coupled line 320 and the impedance control circuit 330 may be substantially the same as the input port PT1, the output port PT2, the coupled port PT3, the isolation port PT4, the signal line 110, the coupled line 120 and the second impedance control circuit 140 in FIG. 1, respectively.

As described with reference to FIGS. 11 and 12, even if only one impedance control circuit including the active inductor is included, the circuit size may be reduced and the area utilization may be improved. In addition, since the impedance of the specific port may be adjusted, controlled, and changed in real time and/or dynamically, isolation degradation may be prevented and loss may be reduced or minimized, so that the coupler circuits 200 and 300 may have improved or enhanced performance.

FIG. 13 is a block diagram illustrating an electronic device according to example embodiments.

Referring to FIG. 13, an electronic device 500 includes a first circuit 510, a second circuit 520, and a coupler circuit 530.

The first circuit 510 generates and outputs a signal SIG to be transmitted to the second circuit 520. The second circuit 520 receives the signal SIG, and operates based on the signal SIG. The coupler circuit 530 is disposed or arranged between the first circuit 510 and the second circuit 520, and transmits the signal SIG from the first circuit 510 to the second circuit 520.

The coupler circuit 530 may be the coupler circuit according to example embodiments described with reference to FIGS. 1 through 12. For example, the coupler circuit 530 may include at least one active inductor 532, and may include at least one impedance control circuit as described with reference to FIGS. 1, 11, and 12. As compared with a coupler circuit in related art in which a passive inductor is used, the circuit size may be reduced and the area utilization may be improved, and the impedance of a specific port may be adjusted, controlled, and changed in real time and/or dynamically using the active inductor 532. Accordingly, isolation degradation may be prevented and loss may be reduced or minimized, so that the coupler circuit 530 may have improved or enhanced performance.

In some example embodiments, the electronic device 500 may be an arbitrary electronic device such as a mobile phone, a smart phone, a tablet computer, a laptop computer, a personal digital assistant (PDA), a portable multimedia player (PMP), a digital camera, a portable game console, a music player, a camcorder, a video player, a navigation device, a wearable device, an internet of things (IoT) device, an internet of everything (IoE) device, an e-book reader, a virtual reality (VR) device, an augmented reality (AR) device, a robotic device, a drone, an automotive, etc.

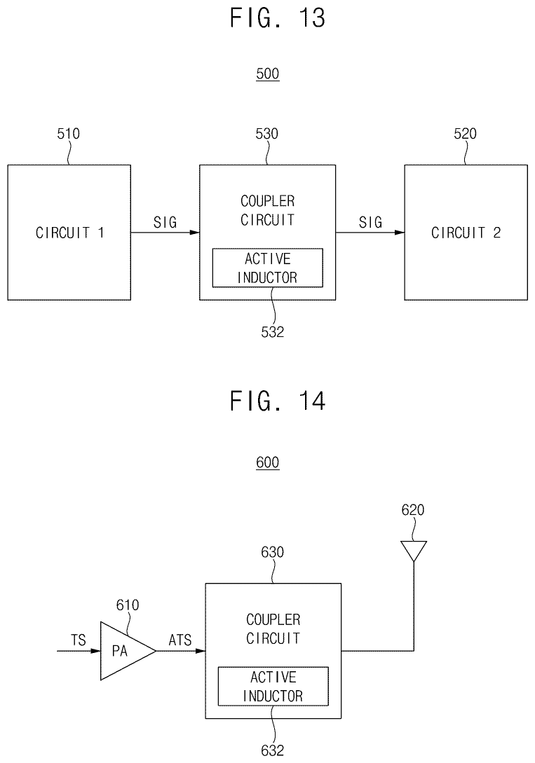

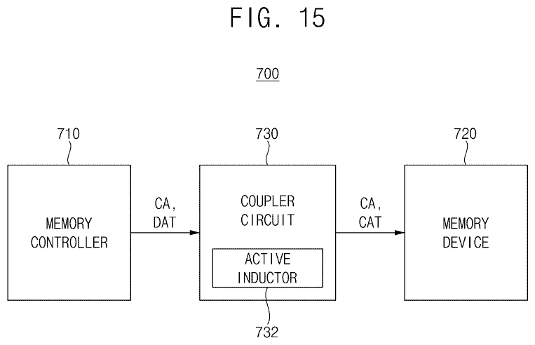

FIGS. 14 and 15 are block diagrams illustrating examples of an electronic device of FIG. 13.

Referring to FIG. 14, an example where the electronic device 500 of FIG. 13 is an RF transmitter that generates and outputs an RF signal is illustrated.

An RF transmitter 600 may include a power amplifier (PA) 610, an antenna 620, and a coupler circuit 630.

The power amplifier 610 may amplify a first signal (or transmission signal) TS, and may generate an amplified first signal ATS. For example, the first signal TS and/or the amplified first signal ATS may be the RF signal. The antenna 620 may output the amplified first signal ATS to the outside. The coupler circuit 630 may be disposed or arranged between the power amplifier 610 and the antenna 620, and may transmit the amplified first signal ATS from the power amplifier 610 to the antenna 620.

The coupler circuit 630 may be the coupler circuit according to example embodiments described with reference to FIGS. 1 through 12. For example, the coupler circuit 630 may include at least one active inductor 632, and may include at least one impedance control circuit as described with reference to FIGS. 1, 11, and 12. As compared with a coupler circuit in related art in which a passive inductor is used, the circuit size may be reduced and the area utilization may be improved, and the impedance of a specific port may be adjusted, controlled, and changed in real time and/or dynamically using the active inductor 632. Accordingly, isolation degradation may be prevented and loss may be reduced or minimized, so that the coupler circuit 630 may have improved or enhanced performance.

In some example embodiments, the power amplifier 610 and the coupler circuit 630 may be implemented in the form of a single semiconductor chip or may be implemented in the form of two separate semiconductor chips.

Although not illustrated in FIG. 14, the RF transmitter 600 may further include a transmission circuit. The transmission circuit may be disposed or arranged in front of the power amplifier 610, may generate the first signal TS based on first data provided from an external processor, and may include, for example, a mixer, an analog filter, etc.

Referring to FIG. 15, an example where the electronic device 500 of FIG. 13 is a memory system that stores data is illustrated.

A memory system 700 may include a memory controller 710, a memory device 720, and a coupler circuit 730. The memory controller 710 may output a command/address signal CA for controlling the memory device 720 and data DAT to be stored in the memory device 720. The memory device 720 may receive the command/address signal CA and data DAT, and may store the data DAT based on the command/address signal CA. The coupler circuit 730 may be disposed or arranged between the memory controller 710 and the memory device 720, and may transmit the command/address signal CA and the data DAT from the memory controller 710 to the memory device 720.

The coupler circuit 730 may be the coupler circuit according to example embodiments described with reference to FIGS. 1 through 12. For example, the coupler circuit 730 may include at least one active inductor 732, and may include at least one impedance control circuit as described with reference to FIGS. 1, 11, and 12. As compared with a coupler circuit using a passive inductor in related art, the circuit size may be reduced and the area utilization may be improved, and the impedance of a specific port may be adjusted, controlled, and changed in real time and/or dynamically using the active inductor 732. Accordingly, isolation degradation may be prevented and loss may be reduced or minimized, so that the coupler circuit 730 may have improved or enhanced performance.

In some example embodiments, the memory device 720 may be an arbitrary volatile and/or nonvolatile memory device such as a static random access memory (SRAM), a dynamic random access memory (DRAM), a flash memory, a phase-change random access memory (PRAM), a resistive random access memory (RRAM), a magnetic random access memory (MRAM), a ferroelectric random access memory (FRAM), etc.

The example embodiments may be applied to various electronic devices and systems that include the coupler circuits. For example, the example embodiments may be applied to systems such as a personal computer (PC), a server computer, a data center, a workstation, a mobile phone, a smart phone, a tablet computer, a laptop computer, a personal digital assistant (PDA), a portable multimedia player (PMP), a digital camera, a portable game console, a music player, a camcorder, a video player, a navigation device, a wearable device, an internet of things (IoT) device, an internet of everything (IoE) device, an e-book reader, a virtual reality (VR) device, an augmented reality (AR) device, a robotic device, a drone, an automotive, etc.

As used herein, the term “at least one of” can refer to and encompass any and all possible combinations of one or more of the associated listed terms. For example, the term “at least one of A, B, or C” means that (i) at least one of A, (ii) at least one of B, (iii) at least one of C, (iv) at least one of A and at least one of B, (v) at least one of B and at least one of C, (vi) at least one of A and at least one of C, or (vi) at least one of A, at least one of B and at least one of C are possible, where A, B and C may be singular or plural.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The foregoing is illustrative of example embodiments and is not to be construed as limiting thereof. Although some example embodiments have been described, those skilled in the art will readily appreciate that many modifications are possible in the example embodiments without materially departing from the novel teachings and advantages of the example embodiments. Accordingly, all such modifications are intended to be included within the scope of the example embodiments as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A coupler circuit comprising:
a signal line between an input port and an output port;
a coupled line between a coupled port and an isolation port;
a first impedance control circuit including a first active inductor, the first impedance control circuit electrically connected to the isolation port and configured to adjust a first impedance of the isolation port; and
a second impedance control circuit including a second active inductor, the second impedance control circuit electrically connected to the output port and configured to adjust a second impedance of the output port,
wherein the first active inductor and the second active inductor are free of a passive element.

2. The coupler circuit of claim 1, wherein the first active inductor includes:
a first current source electrically connected between a power supply voltage and a first node;
a first transistor electrically connected between the power supply voltage and a second node, the first transistor including a first gate electrode electrically connected to the first node;
a second transistor electrically connected between the first node and a ground voltage, the second transistor including a second gate electrode electrically connected to the second node; and
a second current source electrically connected between the second node and the ground voltage.

3. The coupler circuit of claim 2, wherein the first current source is configured generate a first current, the second current source is configured to generate a second current, and at least one of the first current or the second current is adjustable.

4. The coupler circuit of claim 2, wherein the first impedance control circuit includes:
a third transistor electrically connected between the second node and the isolation port; and
a fourth transistor and a first capacitor electrically connected in series between the isolation port and the ground voltage.

5. The coupler circuit of claim 4, wherein the third transistor is configured to control an electrical connection between the first active inductor and the isolation port, and
wherein the fourth transistor is configured to control an electrical connection between the first capacitor and the isolation port.

6. The coupler circuit of claim 4, wherein the third transistor and the first active inductor are configured to decrease an imaginary part of the first impedance, and
wherein the fourth transistor and the first capacitor are configured to increase the imaginary part of the first impedance.

7. The coupler circuit of claim 4, wherein a capacitance of the first capacitor is adjustable.

8. The coupler circuit of claim 2, wherein the first impedance control circuit includes:
a third transistor electrically connected between the second node and the isolation port; and
a fifth transistor and a first resistor electrically connected in series between the isolation port and the ground voltage.

9. The coupler circuit of claim 8, wherein the third transistor is configured to control an electrical connection between the first active inductor and the isolation port, and
wherein the fifth transistor is configured to control an electrical connection between the first resistor and the isolation port.

10. The coupler circuit of claim 8, wherein the third transistor and the first active inductor are configured to decrease an imaginary part of the first impedance, and
wherein the fifth transistor and the first resistor are configured to increase the imaginary part of the first impedance.

11. The coupler circuit of claim 10, wherein a resistance of the first resistor is adjustable.

12. The coupler circuit of claim 2, wherein the first impedance control circuit includes:
a third transistor electrically connected between the second node and the isolation port;
a fourth transistor and a first capacitor electrically connected in series between the isolation port and the ground voltage; and
a fifth transistor and a first resistor electrically connected in series between the isolation port and the ground voltage.

13. The coupler circuit of claim 1, comprising:
a control signal generating circuit configured to generate a first impedance control signal for controlling the first impedance, provide the first impedance control signal to the first impedance control circuit, generate a second impedance control signal for controlling the second impedance, and provide the second impedance control signal to the second impedance control circuit.

14. The coupler circuit of claim 13, wherein the control signal generating circuit is configured to generate the first and second impedance control signals based on at least one of a first signal passing through the signal line or a second signal detected from the coupled port.

15. The coupler circuit of claim 1, wherein the second impedance control circuit has a same configuration as the first impedance control circuit.

16. The coupler circuit of claim 1, wherein the second impedance control circuit has a different configuration from the first impedance control circuit.

17. An electronic device comprising:
a first circuit configured to generate a first signal;
a second circuit configured to receive the first signal; and
a coupler circuit between the first circuit and the second circuit, the coupler circuit configured to transmit the first signal from the first circuit to the second circuit,
wherein the coupler circuit includes:
a signal line between an input port configured to receive the first signal and a output port configured to output the first signal;
a coupled line between a coupled port and an isolation port;
a first impedance control circuit including a first active inductor, the first impedance control circuit electrically connected to the isolation port and configured to adjust a first impedance of the isolation port; and
a second impedance control circuit including a second active inductor, the second impedance control circuit electrically connected to the output port and configured to adjust a second impedance of the output port, and
wherein the first active inductor and the second active inductor are free of a passive element.

18. The electronic device of claim 17, wherein the first signal includes a radio frequency (RF) signal, and the electronic device includes an RF transmitter configured to generate and output the RF signal, and
wherein the first circuit includes a power amplifier configured to generate the RF signal, and the second circuit includes an antenna configured to output the RF signal.

19. A coupler circuit comprising:
a signal line between an input port and an output port;
a coupled line between a coupled port and an isolation port; and
a first impedance control circuit electrically connected to the isolation port and configured to adjust a first impedance of the isolation port,
wherein the first impedance control circuit includes:
a first active inductor configured to adjust the first impedance, wherein the first active inductor includes:
a first current source electrically connected between a power supply voltage and a first node;
a first transistor electrically connected between the power supply voltage and a second node, the first transistor including a first gate electrode electrically connected to the first node;
a second transistor electrically connected between the first node and a ground voltage, the second transistor including a second gate electrode electrically connected to the second node; and
a second current source electrically connected between the second node and the ground voltage;
a third transistor electrically connected between the second node and the isolation port, the third transistor configured to control an electrical connection between the first active inductor and the isolation port;
a first capacitor configured to adjust the first impedance;
a fourth transistor electrically connected between the first capacitor and the isolation port, the fourth transistor configured to control an electrical connection between the first capacitor and the isolation port;
a first resistor configured to adjust the first impedance; and
a fifth transistor electrically connected between the first resistor and the isolation port, the fifth transistor configured to control an electrical connection between the first resistor and the isolation port.

20. The coupler circuit of claim 19, comprising:
a second impedance control circuit electrically connected to the output port and configured to adjust a second impedance of the output port,
wherein the second impedance control circuit includes:
a second active inductor configured to adjust the second impedance, wherein the second active inductor includes:
a third current source electrically connected between the power supply voltage and a third node;
a sixth transistor electrically connected between the power supply voltage and a fourth node, the sixth transistor including a third gate electrode electrically connected to the third node;
a seventh transistor electrically connected between the third node and the ground voltage, the seventh transistor including a fourth gate electrode electrically connected to the fourth node; and
a fourth current source electrically connected between the fourth node and the ground voltage;
an eighth transistor electrically connected between the fourth node and the output port, the eighth transistor configured to control an electrical connection between the second active inductor and the output port;
a second capacitor configured to adjust the second impedance;
a ninth transistor electrically connected between the second capacitor and the output port, the ninth transistor configured to control an electrical connection between the second capacitor and the output port;
a second resistor configured to adjust the second impedance; and
a tenth transistor electrically connected between the second resistor and the output port, the tenth transistor configured to control an electrical connection between the second resistor and the output port.
